(19) United States
(12) Patent Application Publication
(10) Pub. No.: US 2011/0187464 A1
(43) Pub. Date: Aug. 4, 2011

(54) APPARATUS AND METHODS FOR ALKALI VAPOR CELLS

(75) Inventors: Daniel W. Youngner, Maple Grove, MN (US); Jeff A. Ridley, Shorewood, MN (US); Son T. Lu, Plymouth, MN (US); Mary Salit, Plymouth, MN (US)

(73) Assignee: HONEYWELL INTERNATIONAL INC., Morristown, NJ (US)

(21) Appl. No.: 12/873,441

(22) Filed: Sep. 1, 2010

Related U.S. Application Data
(60) Provisional application No. 61/301,497, filed on Feb. 4, 2010.

(51) Int. Cl. H01S 1/06; H03B 17/00; B23K 31/02

(52) U.S. Cl. 331/94.1; 228/121

(57) ABSTRACT

Apparatus and methods for alkali vapor cells are provided. In one embodiment, a vapor cell for a Chip-Scale Atomic Clocks (CSAC) comprises a silicon wafer having defined within a first chamber, a second chamber, and a pathway connecting the first chamber to the second chamber; a first glass wafer anodically-bonded to a first surface of the silicon wafer; a second glass wafer anodically-bonded to an opposing second surface of the silicon wafer, wherein the first chamber defines an optical path through the vapor cell; and an alkali metal material deposited into the second chamber. The pathway connecting the first chamber to the second chamber is configured with a geometry that is at least partially inhibitive to alkali metal vapor flow.

### CROSS-REFERENCE TO RELATED APPLICATION

This application claims the benefit of U.S. Provisional Patent Application Ser. No. 61/301,497, filed on Feb. 4, 2010, which is incorporated herein by reference.

### GOVERNMENT LICENSE RIGHTS

The U.S. Government may have certain rights in the present invention as provided for by the terms of a Government Contract prime numbers FA8650-01-C-1125 and FA8650-01-C-1125 with the U.S. Air Force.

### BACKGROUND

Chip-Scale Atomic Clocks (CSACs) contain vapors of alkali metals—typically either rubidium (Rb) or cesium (Cs). A bichromatic (2 wavelength) optical field is sent through the vapor, exciting hyperfine transitions using a phenomena called coherent population trapping (CPT). A rubidium-based CSAC, for example, works by exciting the D1 hyperfine transition using a vcsel that is tuned to the broad absorption at 795 nm and RF modulated at 3.417 GHz—precisely half the D1 transition frequency. In the early days of CSACs, Cs was preferred over Rb because readily available vcsels at 852 nm could be used to excite hyperfine transitions in 133Cs vapors. More recently as 795 nm vcsels have continued to mature, Rb has been gaining favor. Rubidium with its simpler Zeeman structure provides better S/N than Cs, and with its lower vapor pressure allows CSACs to operate at higher temperatures.

Contaminants in the optical path of a Chip-Scale Atomic Clock (CSAC) can adversely affect the signal-to-noise (S/N) ratio and the temperature sensitivity of the CSAC. During manufacturing of anodically-bonded alkali vapor cells for such Chip-Scale Atomic Clocks, it is not uncommon for contaminants including water, oxygen, and organic materials, to find their way into the cell. Subsequently, during anodic bonding alkali metal vapor will react with these contaminants, forming precipitates and particulates that partially occlude the optical path.

For the reasons stated above and for other reasons stated below which will become apparent to those skilled in the art upon reading and understanding the specification, there is a need in the art for designs and processes that eliminate or significantly avoid the presence of contaminants in the optical path.

### SUMMARY

The Embodiments of the present invention provide methods and systems for designs and processes that eliminate or significantly avoid the presence of contaminants in the optical path and will be understood by reading and studying the following specification.

In one embodiment, a vapor cell comprises a silicon wafer having defined within a first chamber, a second chamber, and a pathway connecting the first chamber to the second chamber; a first glass wafer anodically-bonded to a first surface of the silicon wafer; a second glass wafer anodically-bonded to an opposing second surface of the silicon wafer, wherein the first chamber defines an optical path through the vapor cell; and an alkali metal material deposited into the second chamber. The pathway connecting the first chamber to the second chamber is configured with a geometry that is at least partially inhibitive to alkali metal vapor flow.

### DRAWINGS

Embodiments of the present invention can be more easily understood and further advantages and uses thereof more readily apparent, when considered in view of the description of the preferred embodiments and the following figures in which:

FIG. 1 is a diagram of a chip-scale atomic clock of one embodiment of the present invention;

FIG. 2 is a diagram of a silicon wafer layer for a vapor cell of a chip-scale atomic clock of one embodiment of the present invention; and

FIG. 3 is a flow chart illustrating a method of one embodiment of the present invention.

In accordance with common practice, the various described features are not drawn to scale but are drawn to emphasize features relevant to the present invention. Reference characters denote like elements throughout figures and text.

### DETAILED DESCRIPTION

In the following descriptions, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical, electrical and method changes may be made without departing from the scope of the present invention. The following detailed description is, therefore, not to be taken in a limiting sense. Further, the various sections of this specification are not intended to be read in isolation but considered together with the teachings of the written description as a whole.

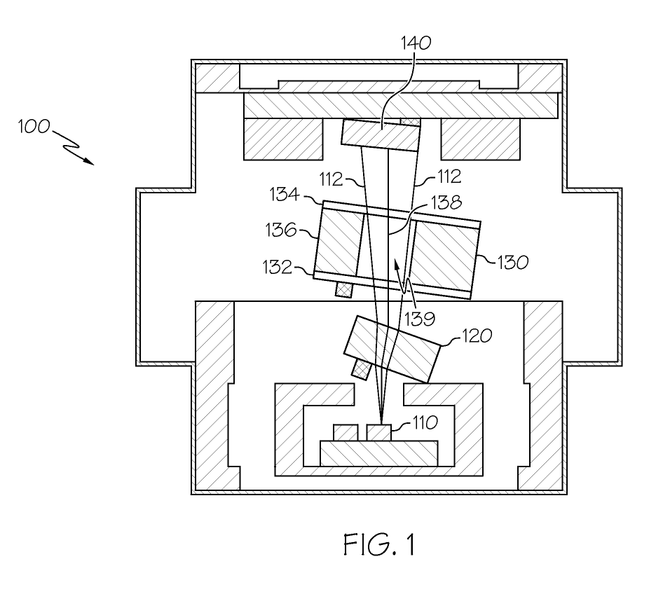

FIG. 1 provides an illustration of a CSAC 100 of one embodiment of the present invention. CSAC 100 comprises a vertical cavity surface emitting laser 110 (vcsel), a quarter wave plate (QWP)/neutral density filter (NDF) 120, a vapor cell 130 and a photo detector 140.

In one embodiment of the present invention, anodic bonding is used during production of vapor cell 130 to seal optically clear glass wafers 132 and 134 (for example, Pyrex or similar glass) to a silicon wafer substrate 136. At least one chamber 138 defined within vapor cell 130 to provides an optical path (shown at 139) between vcsel 110 and photo detector 140 for laser light 112 transmitted by vcsel 110. One benefit of using Pyrex type glasses for glass wafers 132 and 134 is that their structures include a significant quantity of mobile sodium ions. Thus when a respective Pyrex glass wafer (132, 134) is pressed against the silicon wafer 136, and a positive voltage is applied across from the silicon to the Pyrex, oxygen ions will migrate from the respective Pyrex wafer to the surface of the silicon wafer. The migrating oxygen ions will chemically react with the silicon to form SiO₂, which is the substance that holds and seals the wafers 132, 134 and 136 together. Such bonding typically is accomplished at temperatures between 250 and 400 Celsius. The bonding process is performed with the wafers 132, 134, 136 either under high vacuum or backfilled with a buffer gas, such as an Argon-Nitrogen mixture.

In one embodiment of the present inventor, a first glass wafer 132 is initially bonded to a base side of the silicon wafer 136 after which the Rubidium, or other alkali metal (either in liquid or solid form) is deposited into an appropriate chamber (as detailed further below). The second glass wafer 134 is bonded to the opposing side of the silicon wafer 136 to form the vapor cell 130. When a buffer gas is used, the manufacturing equipment containing the components for vapor cell 130 is evacuated, after which the selected buffer gas is backfilled in. Thus, when the bonding is completed to seal vapor cell 130, the alkali metal and optional buffering gas are trapped within the chambers defined within silicon wafer 136.

As would be appreciated by one of ordinary skill in the art upon reading this specification, during the boding process some of the migrating oxygen ions will drift into any chamber holding the alkali metal and react to form an oxide material (such as Rubidium oxide or Cesium oxide, for example). The resulting oxide material forms a crust that scatters or blocks light. Consequently, the formation of any oxide material within the optical path 139 will degrade performance of the CSAC 100.

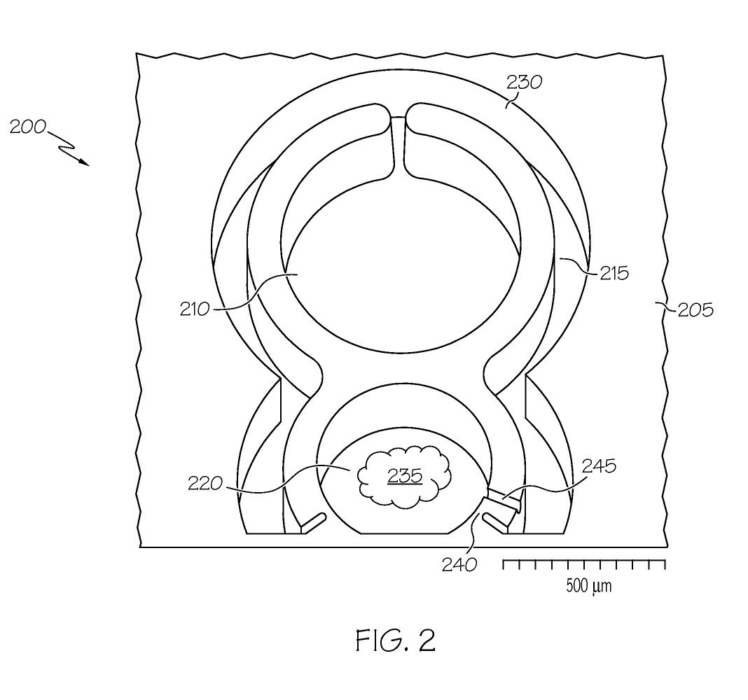

FIG. 2 is a diagram illustrating a vapor cell 200 for a CSAC of one embodiment of the present invention. Vapor cell 200 comprises a silicon wafer 205 in which a first chamber 210, a second chamber 220 and at least one connecting pathway 215 are defined. As would be appreciated by one of ordinary skill in the art upon reading this specification, the chambers 210, 220 and pathway 215 are sealed within Vapor cell 200 between glass wafers (such as glass wafers 132, 134) as described above for FIG. 1.

For the embodiment shown in FIG. 2, the first chamber 210, comprises part of the optical path for the CSAC 100 and must be kept clean for the reasons described above. The Rubidium or other alkali metal (shown generally at 235) is deposited as a liquid or solid into the second chamber 220. Connecting pathway 215 establishes what can be characterized as a “tortuous path” (illustrated generally by 230) for the alkali metal vapor molecules to travel from the second chamber 220 to the first chamber 210. The particular connecting pathway 215 shown in the embodiment of FIG. 2 comprises combinations of straight segments, right angle corner segments and curved segments. Because of the dynamics of gas molecules, the alkali metal vapor molecules do not flow smoothly through such pathway geometries, but rather bounce off of the walls and frequently stick to walls. Accordingly, other pathway geometries would be recognized by those of ordinary skill in the art upon reading this specification as being at least partially inhibitive to alkali metal vapor flow through silicon material and such geometries are collectively referred to herein as a “tortuous path” and contemplated as within the scope of embodiments of the present invention.

Because connecting pathway 215 slows the flow of alkali metal vapor molecules into the first chamber 210, during the anodic bonding process contaminants and precipitates are largely confined to the proximity of the second chamber 210. That is, any contaminants that may exist in the optically active first chamber 210 (e.g. water, O2, organics) will to some degree mingle and react with the alkali metal vapor, but that reaction will occur predominantly in or near to the second chamber 220 rather than in the optically active first chamber 210. Moreover, the fact that the alkali atoms briefly stick to the chamber walls when they collide with the walls causes the net rate of migration of the alkali atoms from the second chamber 220 toward the first chamber 210 to be much slower than the net rate of migration of oxygen and water from first chamber 210 toward second chamber 220. The slow rate of migration of alkali atoms further ensures that most of the precipitates will be largely confined near the second chamber 220.

In one embodiment, the second chamber 220 is isolated from the connecting pathway 215 except for a shallow trench 245 (50 um deep, for example) to further slow migration of alkali metal vapor from the second chamber 220.

In one embodiment, the second chamber 220 is hermetically isolated from the first chamber 210. Thus, during anodic bonding the contaminants and precipitates that might react with the alkali metal vapor are largely confined to the second chamber 220. After bonding, a portion of a wall (such as shown generally at 240) that separates the second chamber 220 from the connecting pathway 215, is obliterated using a laser to allow the alkali metal vapor to migrate to the first chamber 210.

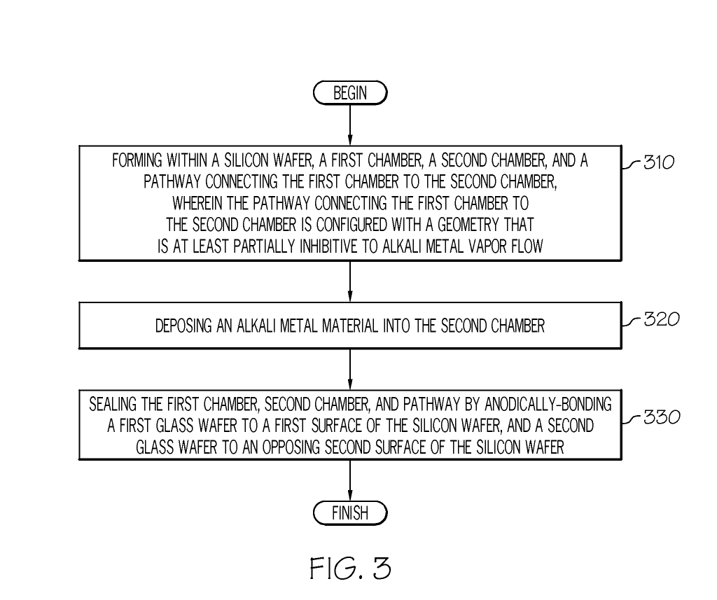

FIG. 3 is a flow chart illustrating a method for one embodiment of the present invention. The method begins at 310 with forming within a silicon wafer, a first chamber, a second chamber, and a pathway connecting the first chamber to the second chamber. Typically, the silicon wafer is anodically bonded to a lower Pyrex or other transparent wafer, as further described for 330, below, thereby forming a floor for the chambers. The pathway connecting the first chamber to the second chamber is configured with a geometry that is at least partially inhibitive to alkali metal vapor flow. As used herein, the term “at least partially inhibitive” is used to mean that the pathway slows the migration of alkali metal vapor through the path, but does not completely prevent such flow. In one embodiment, the pathway comprises one or more right angle corner segments and/or curved segments in order to provide a geometry that is at least partially inhibitive to alkali metal vapor flow. In one embodiment, the method further comprises forming a trench between with second chamber and the pathway, which in one embodiment is approximately 50 um in depth. Because the path is at least partially inhibitive to alkali metal vapor flow, during the anodic bonding discussed below contaminants and precipitates are largely confined to the proximity of the second chamber, thus avoiding the formation of light blocking oxide contaminants in the first chamber.

The method proceeds to 320 with depositing an alkali metal material into the second chamber. In alternate embodiments, the alkali metal material can comprise either Rubidium or Cesium, and may be in either solid or liquid form.

The method proceeds to 330 with sealing the first chamber, second chamber, and pathway by anodically-bonding a first glass wafer to a first surface of the silicon wafer, and a second glass wafer to an opposing second surface of the silicon wafer. The first chamber defines part of an optical path for the CSAC. For example, referring to the particular embodiment of FIG. 1, the first chamber provides an optical path for laser light from vcsel 110 to photo detector 140.

In one embodiment, in the sealing process defined at block 330, a glass wafer containing a mobile ion such as sodium is brought into contact with a silicon wafer, with an electrical contact to both the glass and silicon. This causes the sodium in the glass to move toward the negative electrode, and allows for more voltage to be dropped across the gaps between the glass and silicon, causing more intimate contact. At the same time, oxygen ions are released from the glass and flow toward the silicon, and help to form a bridge between the silicon in the glass and the silicon in the silicon wafer. This joint can be very strong. The process can be operated with a wide variety of background gases and pressures, from well above atmospheric to high vacuum. Higher gas pressures improve heat transfer, and speed up the process. If the wafers are patterned with etched cavities, these cavities can have the desired gas sealed inside.

In one embodiment, during anodically-bonding the first chamber is hermetically isolated from the second chamber. Thus, during anodic bonding contaminants and precipitates that might react with the alkali metal vapor are largely confined to the second chamber. After bonding, a portion of a wall that separates the second chamber from the connecting pathway, is obliterated, such as by using a laser for example. This allows the alkali metal vapor to migrate to the first chamber after boding is completed, avoiding formation of light blocking oxide material within the first chamber.

Although the embodiments above generally describe embodiments of Alkali Vapor Cells utilized in the context of Chip-Scale Atomic Clocks, embodiments of the present invention are not only limited to Chip-Scale Atomic Clock applications. Other applications for Alkali Vapor Cells are contemplated as within the scope of embodiments of the present invention.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A method for making anodically-bonded alkali vapor cells, the method comprising:
forming within a silicon wafer, a first chamber, a second chamber, and a pathway connecting the first chamber to the second chamber;
depositing an alkali metal material into the second chamber; and
sealing the first chamber, second chamber, and pathway by anodically-bonding a first glass wafer to a first surface of the silicon wafer, and a second glass wafer to an opposing second surface of the silicon wafer, wherein the first chamber defines part of an optical path;
wherein the pathway connecting the first chamber to the second chamber is configured with a geometry that is at least partially inhibitive to alkali metal vapor flow.

2. The method of claim 1, wherein the alkali metal material comprises either a liquid or a solid material.

3. The method of claim 1, wherein the alkali metal material comprises one of Rubidium or Cesium.

4. The method of claim 1, wherein during the anodic-bonding, the first chamber is hermetically isolated from the second chamber; and
wherein after bonding, the method further comprises obliterating at least part of a wall that separates the first chamber from the pathway.

5. The method of claim 4, wherein obliterating the wall further comprises obliterating at least part of the wall with a laser.

6. The method of claim 1, further comprising forming a trench between with second chamber and the pathway.

7. The method of claim 6, wherein the trench has a depth of approximately 50 um.

8. The method of claim 1, wherein the pathway comprises at least one of either a straight segment, a right angle corner segment or a curved segment, or a combination of straight segments, right angle corner segments and curved segments.

9. A vapor cell, the vapor cell comprising:
a silicon wafer having defined within a first chamber, a second chamber, and a pathway connecting the first chamber to the second chamber;
a first glass wafer anodically-bonded to a first surface of the silicon wafer;
a second glass wafer anodically-bonded to an opposing second surface of the silicon wafer;
wherein the first chamber defines an optical path through the vapor cell; and
an alkali metal material deposited into the second chamber;
wherein the pathway connecting the first chamber to the second chamber is configured with a geometry that is at least partially inhibitive to alkali metal vapor flow.

10. The vapor cell of claim 9, wherein the alkali metal material comprises either a liquid or a solid material.

11. The vapor cell of claim 9, wherein the alkali metal material comprises one of Rubidium or Cesium.

12. The vapor cell of claim 9, wherein the vapor cell is backfilled with a buffer gas.

13. The vapor cell of claim 9, further comprising a trench formed in the silicon wafer between the second chamber and the pathway.

14. The vapor cell of claim 13, wherein the trench has a depth of approximately 50 um.

15. The vapor cell of claim 9, wherein the pathway comprises at least one of either a straight segment, right angle corner segment or a curved segment, or a combination of straight segments, right angle corner segments and curved segments.

16. A Chip-Scale Atomic Clock (CSAC) comprising:
a vertical cavity surface emitting laser (vcsel);
a vapor cell; and
a photo detector;
wherein the vapor cell comprises a first chamber that defines at least part of an optical path for laser light between the vcsel and the photo detector;
wherein the vapor cell further comprises a second chamber having an alkali metal material deposited therein;
wherein the vapor cell further comprises a pathway connecting the first chamber to the second chamber, the pathway having a geometry that is at least partially inhibitive to alkali metal vapor flow.

17. The Chip-Scale Atomic Clock of claim 16, wherein the alkali metal material comprises one of Rubidium or Cesium.

18. The Chip-Scale Atomic Clock of claim 16, wherein the vapor cell is backfilled with a buffer gas.

19. The Chip-Scale Atomic Clock of claim 16, further comprising a trench formed in a silicon wafer wall between the second chamber and the pathway.

20. The Chip-Scale Atomic Clock of claim 16, wherein the pathway comprises at least one of either a straight segment, a right angle corner segment or a curved segment, or a combination of straight segments, right angle corner segments and curved segments.
